(19) United States
(12) Patent Application Publication
(10) Pub. No.: US 2026/0006809 A1
(43) Pub. Date: Jan. 1, 2026

(54) JUNCTION BARRIER SCHOTTKY DIODE

(71) Applicant: TDK Corporation, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 19/319,866

(22) Filed: Sep. 5, 2025

Related U.S. Application Data
(63) Continuation of application No. PCT/JP2023/044801, filed on Dec. 14, 2023.

(30) Foreign Application Priority Data
Mar. 14, 2023 (JP) 2023-039939

(51) Int. Cl. H10D 8/60; H10D 8/00; H10D 62/10; H10D 64/00

(52) U.S. Cl. CPC H10D 8/60; H10D 8/422; H10D 62/103; H10D 64/111

(57) ABSTRACT

Disclosed herein is a junction barrier Schottky diode that includes: a semiconductor substrate; a drift layer provided on the semiconductor substrate; a field insulating film covering an annular outer peripheral area of an upper surface of the drift layer; an anode electrode brought into Schottky-contact with a center area of the upper surface of the drift layer that is surrounded by the outer peripheral area, an end portion of the anode electrode being positioned on the field insulating film; a cathode electrode brough into ohmic contact with the semiconductor substrate; a p-type semiconductor layer embedded in a first trench formed in the center area of the drift layer so as to be connected to the anode electrode and the drift layer; and a conductive member contacting the field insulating film and electrically connected to the semiconductor substrate.

### CROSS-REFERENCE TO RELATED APPLICATION

This application claims the benefit of Japanese Patent Application No. 2023-039939, filed on Mar. 14, 2023, the entire disclosure of which is incorporated by reference herein.

### BACKGROUND OF THE ART

### Field of the Art

The present disclosure relates to a junction barrier Schottky diode.

### Description of Related Art

A Schottky barrier diode is a rectifying element utilizing a Schottky barrier generated due to bonding between metal and a semiconductor and is lower in forward voltage and higher in switching speed than a normal diode having a PN junction. Thus, the Schottky barrier diode is sometimes utilized as a switching element for a power device.

When the Schottky barrier diode is utilized as a switching element for a power device, it is necessary to ensure a sufficient backward withstand voltage, so that silicon carbide (SiC), gallium nitride (GaN), or gallium oxide (Ga₂O₃) having a larger band gap is sometimes used in place of silicon (Si). Among them, gallium oxide has a very large band gap (4.8 eV to 4.9 eV) and a large breakdown field of 8 MV/cm, so that a Schottky barrier diode using gallium oxide is very promising as the switching element for a power device. An example of the Schottky barrier diode using gallium oxide is described in JP 2019-036593A.

JP 2019-036593A discloses a junction barrier Schottky diode having a structure in which a plurality of trenches provided in a gallium oxide layer are filled with a p-type semiconductor material. By thus providing a plurality of trenches in the gallium oxide layer and filling the plurality of trenches with a p-type semiconductor material, a mesa region positioned between the trenches becomes a depletion layer upon application of a backward voltage, so that a channel region of a drift layer is pinched off. Thus, a leak current upon application of a backward voltage can be significantly reduced.

JP 2019-036593A further discloses a structure in which the end portion of an anode electrode is disposed on a field insulating film provided on the upper surface of a drift layer. When the anode electrode has such a field plate structure, it is possible to relax an electric field to be applied on the drift layer upon application of a backward voltage.

### SUMMARY

A junction barrier Schottky diode according to one aspect of the present disclosure includes: a semiconductor substrate; a drift layer provided on the semiconductor substrate; a field insulating film covering an annular outer peripheral area of an upper surface of the drift layer; an anode electrode brought into Schottky-contact with a center area of the upper surface of the drift layer that is surrounded by the outer peripheral area, an end portion of the anode electrode being positioned on the field insulating film; a cathode electrode brough into ohmic contact with the semiconductor substrate; a p-type semiconductor layer embedded in a first trench formed in the center area of the drift layer so as to be connected to the anode electrode and the drift layer; and a conductive member contacting the field insulating film and electrically connected to the semiconductor substrate.

### BRIEF DESCRIPTION OF THE DRAWINGS

The above features and advantages of the present disclosure will be more apparent from the following description of some embodiments taken in conjunction with the accompanying drawings, in which:

FIG. 1A is a schematic plan view illustrating the configuration of a junction barrier Schottky diode 1 according to a first embodiment of the present disclosure;

FIG. 1B is a schematic cross-sectional view taken along the line A-A in FIG. 1A;

FIG. 2 is a schematic cross-sectional view illustrating the configuration of a junction barrier Schottky diode 2 according to a second embodiment of the technology described herein;

FIG. 3 is a schematic cross-sectional view illustrating the configuration of a junction barrier Schottky diode according to a third embodiment of the technology described herein;

FIG. 4 is a schematic cross-sectional view illustrating the configuration of a junction barrier Schottky diode 4 according to a fourth embodiment of the technology described herein;

FIG. 5A is a schematic plan view illustrating the configuration of a junction barrier Schottky diode 5 according to a fifth embodiment of the technology described herein;

FIG. 5B is a schematic cross-sectional view taken along the line A-A illustrated in FIG. 5A;

FIG. 6 is a schematic cross-sectional view illustrating the configuration of a junction barrier Schottky diode 6 according to a sixth embodiment of the technology described herein;

FIG. 7 is a schematic cross-sectional view illustrating the configuration of a junction barrier Schottky diode 7 according to a seventh embodiment of the technology described herein;

FIG. 8 is a schematic cross-sectional view illustrating the configuration of a junction barrier Schottky diode 8 according to an eighth embodiment of the technology described herein;

FIG. 9 is a schematic cross-sectional view illustrating the configuration of a junction barrier Schottky diode 9 according to a ninth embodiment of the technology described herein;

FIG. 10 is a schematic plan view illustrating the configuration of a junction barrier Schottky diode 10 according to a tenth embodiment of the technology described herein;

FIG. 11 is a schematic plan view illustrating the configuration of a junction barrier Schottky diode 11 according to an eleventh embodiment of the technology described herein;

FIG. 12 is a schematic plan view illustrating the configuration of a junction barrier Schottky diode 12 according to a twelfth embodiment of the technology described herein;

FIG. 13 is a schematic cross-sectional view illustrating the configuration of a junction barrier Schottky diode 13 according to a thirteenth embodiment of the technology described herein;

FIG. 14 is a schematic cross-sectional view illustrating the configuration of a junction barrier Schottky diode 14 according to a fourteenth embodiment of the technology described herein;

FIG. 15 is a schematic cross-sectional view illustrating the configuration of a junction barrier Schottky diode 15 according to a comparative example;

FIG. 16A is a schematic plan view illustrating the wafer 100 before dicing;

FIG. 16B is a schematic cross-sectional view taken along the line A-A illustrated in FIG. 16A;

FIG. 17 is a schematic plan view illustrating a wafer 100 according to a modified example;

FIG. 18 is a graph showing the results of Example 1; and

FIG. 19 is a graph showing the results of Example 2.

### DETAILED DESCRIPTION OF THE EMBODIMENTS

In the junction barrier Schottky diode described in JP 2019-036593A, an electric charge is accumulated upon application of a backward voltage, which sometimes causes a dielectric breakdown at a portion immediately below the field insulating film.

The present disclosure describes a technology for preventing, in a junction barrier Schottky diode, a dielectric breakdown due to accumulation of an electric charge.

Hereinafter, some embodiments of the present disclosure will be described in detail with reference to the accompanying drawings.

### First Embodiment

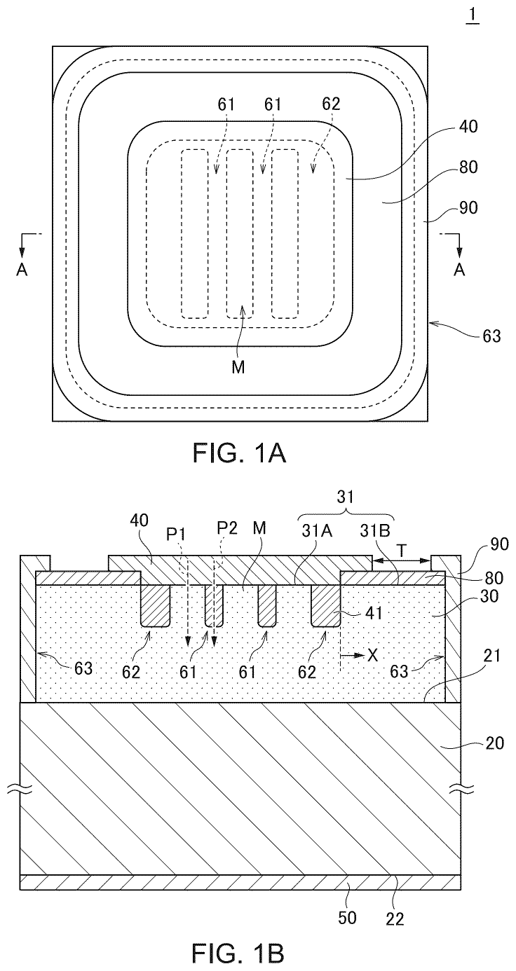

FIG. 1A is a schematic plan view illustrating the configuration of a junction barrier Schottky diode 1 according to a first embodiment of the present disclosure. FIG. 1B is a schematic cross-sectional view taken along the line A-A in FIG. 1A.

As illustrated in FIG. 1, the junction barrier Schottky diode 1 according to the first embodiment has a semiconductor substrate 20 and a drift layer 30, both of which are made of gallium oxide (β-Ga₂O₃). The semiconductor substrate 20 and drift layer 30 are each introduced with silicon (Si) or tin (Sn) as an n-type dopant. The concentration of the dopant is higher in the semiconductor substrate 20 than in the drift layer 30, whereby the semiconductor substrate 20 and the drift layer 30 function as an n⁺ layer and an n-layer, respectively.

The semiconductor substrate 20 is obtained by cutting a bulk crystal formed using a melt-growing method and has a thickness of about 250 μm. The planar size of the semiconductor substrate 20 is not particularly limited and is generally selected in accordance with the amount of current flowing in the element. For example, when the maximum amount of forward current is about 20A, the planar size may be set to be about 2.4 mm×2.4 mm.

The semiconductor substrate 20 has an upper surface 21 positioned on the upper surface side in its mounted state and a back surface 22 positioned opposite the upper surface 12 and on the lower surface side in its mounted state. The drift layer 30 is formed on the entire upper surface 21. The drift layer 30 is a thin film obtained by epitaxially growing gallium oxide on the upper surface 21 of the semiconductor substrate 20 using a reactive sputtering method, a PLD method, an MBE method, an MOCVD method, or an HVPE method. The film thickness of the drift layer 30 is not particularly limited and is generally selected in accordance with the backward withstand voltage of the element. For example, in order to ensure a withstand voltage of about 600 V, the film thickness may be set to be about 10 μm.

An upper surface 31 of the drift layer 30 has an annular outer peripheral area 31B and a center area 31A surrounded by the outer peripheral area 31B. The upper surface 31 of the drift layer 30 is covered, at the outer peripheral area 31B, with a field insulating film 80 made of a silicon oxide, etc. On the other hand, the upper surface 31 of the drift layer 30 has thereon, at the center area 31A, an anode electrode 40 that is brought into Schottky-contact with the drift layer 30. The outer peripheral end portion of the anode electrode 40 is positioned on the field insulating film 80. By adopting such a field plate structure, it is possible to relax an electric field to be applied to the drift layer 30.

The anode electrode 40 is formed of metal such as platinum (Pt), palladium (Pd), gold (Au), nickel (Ni), molybdenum (Mo), or Copper (Cu). The anode electrode 40 may have a multilayer structure of different metal films, such as Pt/Au, Pt/Al, Pd/Au, Pd/Al, Pt/Ti/Au, or Pd/Ti/Au. On the other hand, there is formed, on the back surface 22 of the semiconductor substrate 20, a cathode electrode 50 which is brought into ohmic contact with the semiconductor substrate 20. The cathode electrode 50 is formed of metal such as titanium (Ti). The cathode electrode 50 may have a multilayer structure of different metal films, such as Ti/Au or Ti/Al.

In the present embodiment, the drift layer 30 has a center trench 61 and an outer peripheral trench 62. Both the center and outer peripheral trenches 61 and 62 are formed at the center area 31A, that is, a position overlapping the anode electrode 40 in a plan view and each filled with a p-type semiconductor layer 41 that forms a pn junction with the drift layer 30. As a result, the p-type semiconductor layer 41 contacts both the anode electrode 40 and drift layer 30. Examples of the material of the p-type semiconductor layer 41 may include Si, GaAs, GaN, SiC, Ge, ZnSe, CdS, InP, SiGe, AlN, BN, AlGAN, Nio, Cu₂O, Ir₂O₃, and Ag₂O.

When a forward voltage is applied to the junction barrier Schottky diode 1 according to the present embodiment, two current paths are formed to extend from the anode electrode 40 toward the drift layer 30. The first current path is a path along which a current flows from the anode electrode 40 to the drift layer 30 directly, not through the p-type semiconductor layer 41, as denoted by P1 in FIG. 1B. The second current path is a path along which a current flows from the anode electrode 40 to the drift layer 30 through the p-type semiconductor layer 41, as denoted by P2 in FIG. 1B. Thus, when a higher forward voltage is applied after a current flows in the first current path P1, the second current path P2 is turned ON. As a result, an on-resistance is significantly reduced.

The center trench 61 is sandwiched by a mesa region M constituting a part of the drift layer 30. The outer peripheral trench 62 surrounds, in a ring shape, the mesa region M and center trench 61. The center and outer peripheral trenches 61 and 62 need not completely be separated but may be connected. The depths of the center and outer peripheral trenches 61 and 62 may be the same as or different from each other. The mesa region M is a part of the drift layer 30 that is defined by the center and outer peripheral trenches 61 and 62 and becomes a depletion layer when a backward voltage is applied between the anode electrode 40 and cathode electrode 50, so that a channel region of the drift layer 30 is pinched off, thereby significantly reducing a leak current upon application of a backward voltage.

The drift layer 30 further has a trench 63 formed in a ring shape so as to surround the anode electrode 40 in a plan view as viewed in the stacking direction. The trench 63 is formed so as to reach the semiconductor substrate 20, and thus the semiconductor substrate 20 is exposed to the bottom surface of the trench 63. In the example illustrated in FIGS. 1A and 1B, the upper surface 21 of the semiconductor substrate 20 is exposed to the bottom surface of the trench 63. The inner and outer peripheral walls of the trench 63 have a substantially rectangular shape with rounded corners in a plan view as viewed in the stacking direction. In the example illustrated in FIGS. 1A and 1B, the outer peripheral wall of the trench 63 is partially exposed outside.

The trench 63 is filled with a conductive member 90. The material of the conductive member 90 is not particularly limited and may be a metal material such as Al. Au, Ni, Cu, Pt, or Ti, or a semiconductor material such as polysilicon. The conductive member 90 may be partially made of the same metal material as that of the anode electrode 40. When at least a part of the conductive member 90 is made of the same metal material as that of the anode electrode 40, at least a part of the conductive member 90 can be formed simultaneously with the anode electrode 40.

The conductive member 90 filled in the trench 63 is exposed from the field insulating film 80 and is partially positioned on the field insulating film 80. As a result, the conductive member 90 contacts the field insulating film 80 and outer peripheral area 31B of the upper surface 31 of the drift layer 30 that is covered with the field insulating film 80. Although a distance T between the conductive member 90 and anode electrode 40 on the field insulating film 80 is not particularly limited, when it is set equal to or more than 100 μm, a depletion layer is suppressed from extending in the horizontal direction, thereby achieving higher withstand voltage. Since the trench 63 is formed so as to reach the semiconductor substrate 20, the conductive member 90 is electrically connected to the semiconductor substrate 20. Thus, an electric charge accumulated in the field insulating film 80 upon application of a backward voltage flows in the semiconductor substrate 20 through the conductive member 90. That is, when a backward voltage is applied, a positive electric charge is accumulated around the upper surface 31 of the drift layer 30, so that a negative electric charge is induced in the field insulating film 80 made of a dielectric material. The negative electric charge induced in the field insulating film 80 is extracted to the semiconductor substrate 20 through the conductive member 90 contacting the field insulating film 80, with the result that an electric field to be applied to the drift layer 30 is relaxed.

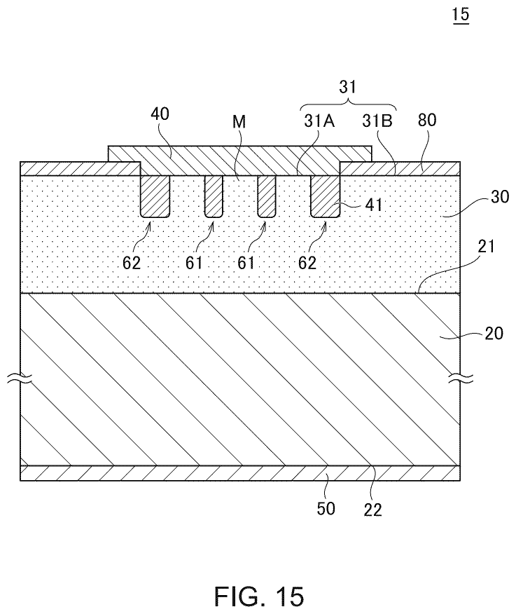

As described above, in the junction barrier Schottky diode 1 according to the present embodiment, the drift layer 30 has the trench 63 formed so as to reach the semiconductor substrate 20, and the conductive member 90 filled in the trench 63 contacts the field insulating film 80, so that an electric charge induced upon application of a backward voltage is extracted to the semiconductor substrate 20. Thus, as compared to when both the trench 63 and conductive member 90 are absent as in a junction barrier Schottky diode 15 according to a comparative example illustrated in FIG. 15, a withstand voltage upon application of a backward voltage can be improved. In addition, in the present embodiment, the trench 63 is formed in a ring shape, allowing an electric charge to be extracted efficiently to the semiconductor substrate 20. Furthermore, the conductive member 90 filled in the trench 63 is exposed from the side of the drift layer 30, so that heat dissipation characteristics can also be improved.

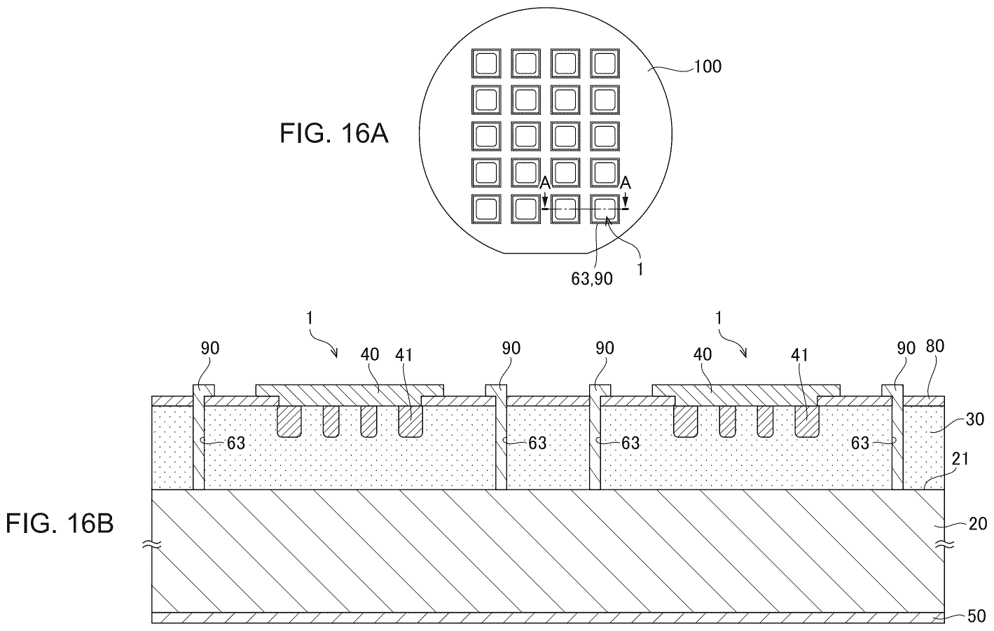

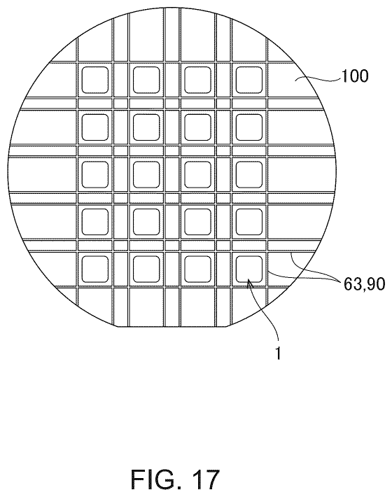

Further, since the trench 63 has a ring shape, the anode electrode 40 and the drift layer 30 positioned immediately therebelow included in the individual junction barrier Schottky diode 1 are each surrounded by the conductive member 90 in a state before dicing (refer to a wafer 100 illustrated in FIG. 16A). FIG. 16B is a schematic cross-sectional view taken along the line A-A illustrated in FIG. 16A. Thus, it is possible to accurately carry out characteristic tests for each junction barrier Schottky diode without being affected by other junction barrier Schottky diodes on the same wafer. The trench 63 and the conductive member 90 filled therein need not be formed for each junction barrier Schottky diode 1 but may be formed in lattice as illustrated in FIG. 17.

### Second Embodiment

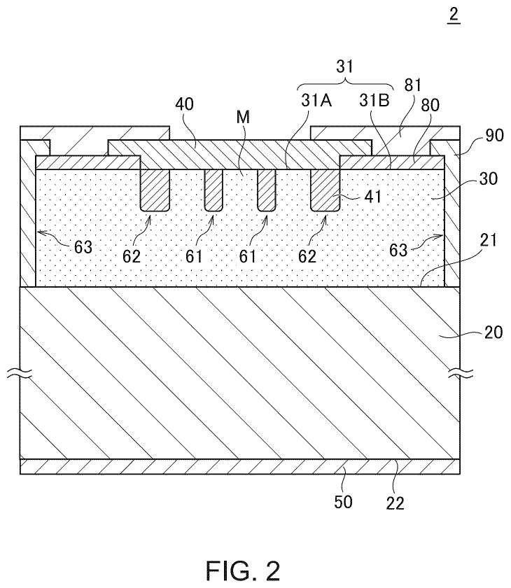

FIG. 2 is a schematic cross-sectional view illustrating the configuration of a junction barrier Schottky diode 2 according to a second embodiment of the technology described herein.

As illustrated in FIG. 2, the junction barrier Schottky diode 2 according to the second embodiment differs from the junction barrier Schottky diode 1 according to the first embodiment in that the outer peripheral portion of the anode electrode 40 and the exposed portions of the field insulating film 80 and conductive member 90 are covered with a protective film 81 made of an insulating material. Other basic configurations are the same as those of the junction barrier Schottky diode 1 according to the first embodiment, so the same reference numerals are given to the same elements, and overlapping description will be omitted. Providing the protective film 81 in this way can further increase product reliability.

### Third Embodiment

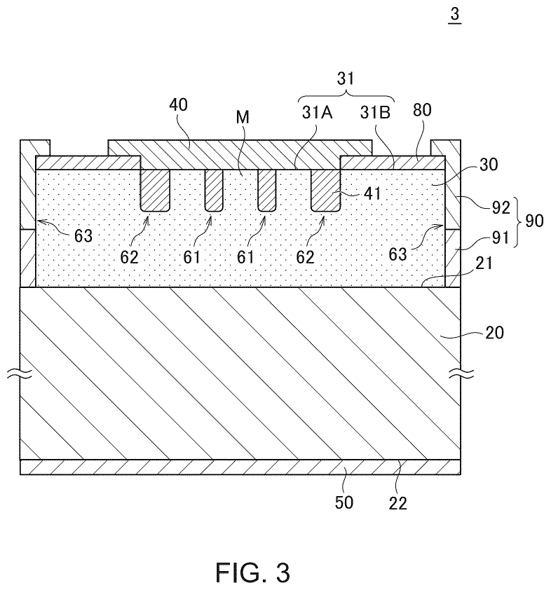

FIG. 3 is a schematic cross-sectional view illustrating the configuration of a junction barrier Schottky diode 3 according to a third embodiment of the technology described herein.

As illustrated in FIG. 3, in the junction barrier Schottky diode 3 according to the third embodiment, the conductive member 90 has a part 91 positioned at the bottom of the trench 63 and a part 92 positioned at the upper portion of the trench 63, which are made of mutually different metal materials. Other basic configurations are the same as those of the junction barrier Schottky diode 1 according to the first embodiment, so the same reference numerals are given to the same elements, and overlapping description will be omitted. When a plurality of metal materials are thus used to constitute the conductive member 90, manufacturing cost may sometimes be reduced. For example, the part 91 at the bottom of the trench 63 can be formed by electrolytic plating, and the part 92 at the upper portion of the trench 63 can be formed simultaneously with the anode electrode 40 by vapor deposition.

### Fourth Embodiment

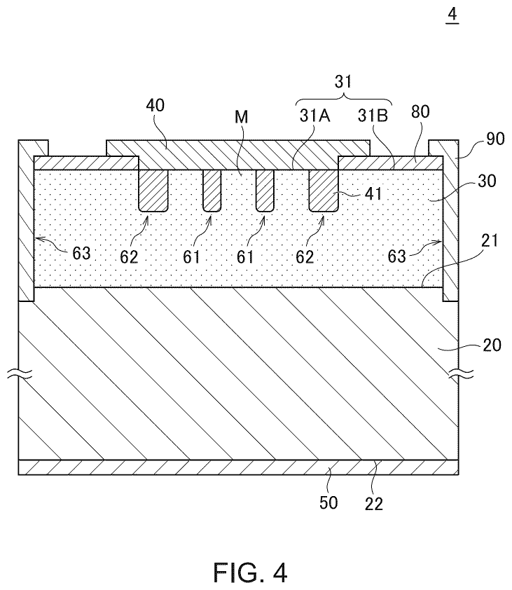

FIG. 4 is a schematic cross-sectional view illustrating the configuration of a junction barrier Schottky diode 4 according to a fourth embodiment of the technology described herein.

As illustrated in FIG. 4, the junction barrier Schottky diode 4 according to the fourth embodiment differs from the junction barrier Schottky diode 1 according to the first embodiment in that the trench 63 is formed deeper. Other basic configurations are the same as those of the junction barrier Schottky diode 1 according to the first embodiment, so the same reference numerals are given to the same elements, and overlapping description will be omitted. When the trench 63 is thus formed deeper beyond the interface between the semiconductor substrate 20 and drift layer 30, the conductive member 90 can be brought into contact reliably with the semiconductor substrate 20 even when the depth of the trench 63 becomes shallower than designed due to manufacturing variation.

### Fifth Embodiment

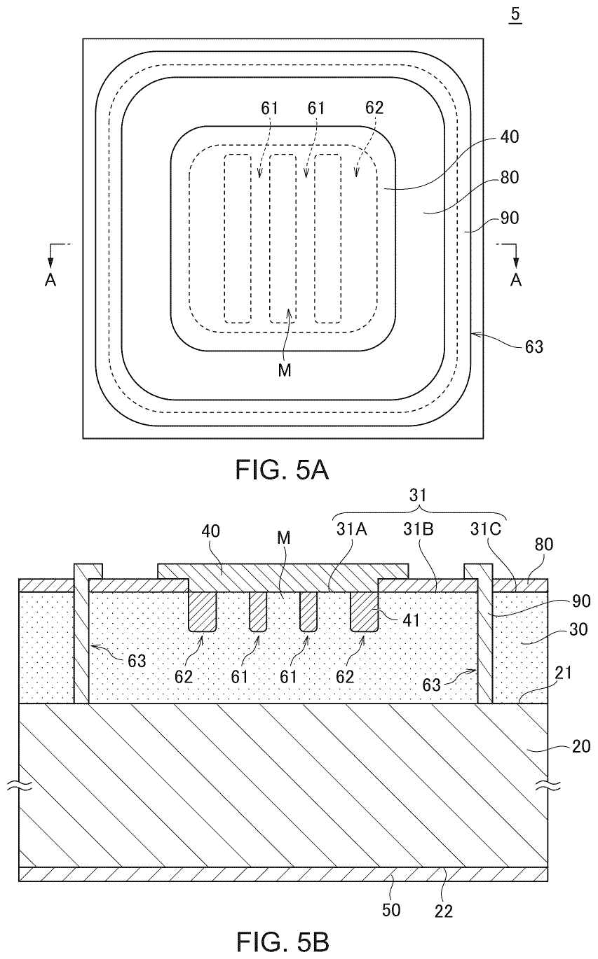

FIG. 5A is a schematic plan view illustrating the configuration of a junction barrier Schottky diode 5 according to a fifth embodiment of the technology described herein. FIG. 5B is a schematic cross-sectional view taken along the line A-A illustrated in FIG. 5A.

As illustrated in FIG. 5, in the junction barrier Schottky diode 5 according to the fifth embodiment, the outer peripheral wall of the trench 63 is not exposed outside, and the drift layer 30 also exists at the outside of the outer peripheral wall of the trench 63. Further, the upper surface 31 of the drift layer 30 has an outermost peripheral area 31C positioned at the outside of the outer peripheral area 31B, and the outermost peripheral area 31C is covered with the field insulating film 80. Other basic configurations are the same as those of the junction barrier Schottky diode 1 according to the first embodiment, so the same reference numerals are given to the same elements, and overlapping description will be omitted. Thus, the drift layer 30 may also exist at the outside of the outer peripheral wall of the trench 63.

### Sixth Embodiment

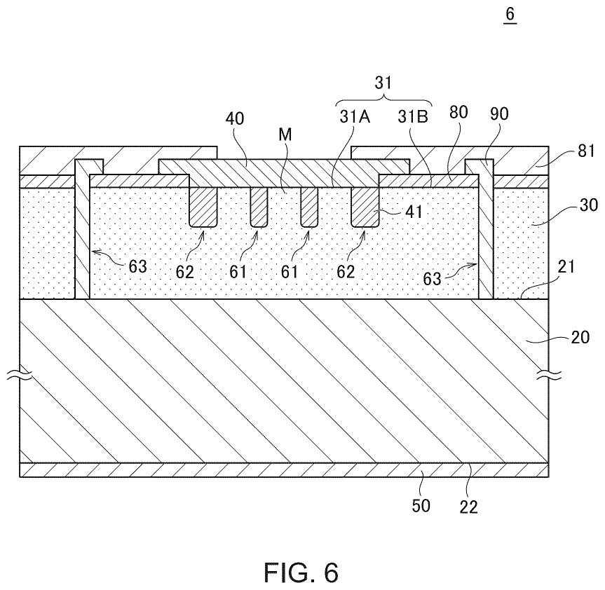

FIG. 6 is a schematic cross-sectional view illustrating the configuration of a junction barrier Schottky diode 6 according to a sixth embodiment of the technology described herein.

As illustrated in FIG. 6, the junction barrier Schottky diode 6 according to the sixth embodiment differs from the junction barrier Schottky diode 5 according to the fifth embodiment in that the outer peripheral portion of the anode electrode 40 and exposed portions of the field insulating film 80 and conductive member 90 are covered with the protective film 81 made of an insulating material. Other basic configurations are the same as those of the junction barrier Schottky diode 5 according to the fifth embodiment, so the same reference numerals are given to the same elements, and overlapping description will be omitted. Providing the protective film 81 in this way can further increase product reliability.

### Seventh Embodiment

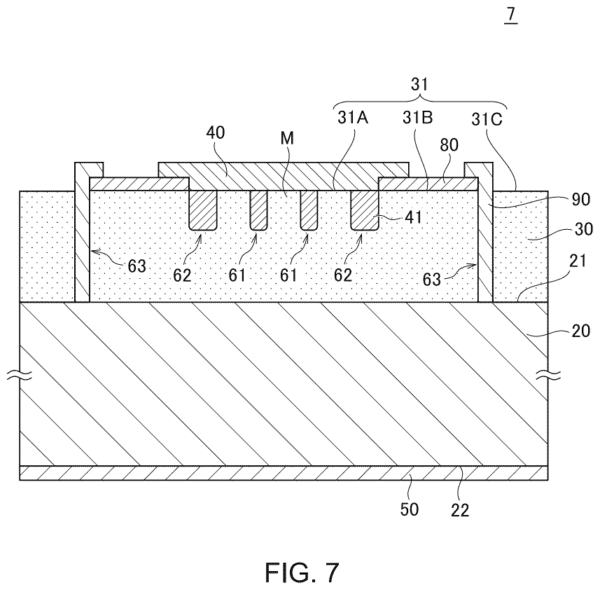

FIG. 7 is a schematic cross-sectional view illustrating the configuration of a junction barrier Schottky diode 7 according to a seventh embodiment of the technology described herein.

As illustrated in FIG. 7, the junction barrier Schottky diode 7 according to the seventh embodiment differs from the junction barrier Schottky diode 5 according to the fifth embodiment in that the outermost peripheral area 31C is not covered with the field insulating film 80. Other basic configurations are the same as those of the junction barrier Schottky diode 5 according to the fifth embodiment, so the same reference numerals are given to the same elements, and overlapping description will be omitted. Thus, the outermost peripheral area 31C need not necessarily be covered with the field insulating film 80.

### Eighth Embodiment

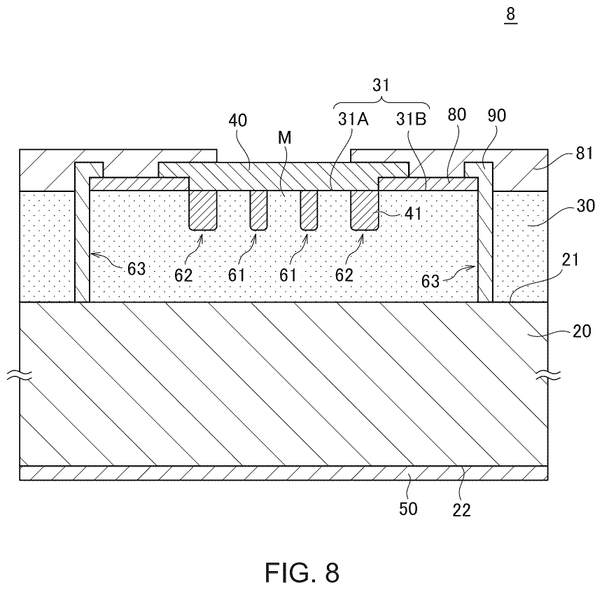

FIG. 8 is a schematic cross-sectional view illustrating the configuration of a junction barrier Schottky diode 8 according to an eighth embodiment of the technology described herein.

As illustrated in FIG. 8, the junction barrier Schottky diode 8 according to the eighth embodiment differs from the junction barrier Schottky diode 7 according to the seventh embodiment in that the outer peripheral portion of the anode electrode 40, the exposed portions of the field insulating film 80 and conductive member 90, and outermost peripheral area 31C are covered with the protective film 81 made of an insulating material. Other basic configurations are the same as those of the junction barrier Schottky diode 7 according to the seventh embodiment, so the same reference numerals are given to the same elements, and overlapping description will be omitted. Providing the protective film 81 in this way can further increase product reliability.

### Ninth Embodiment

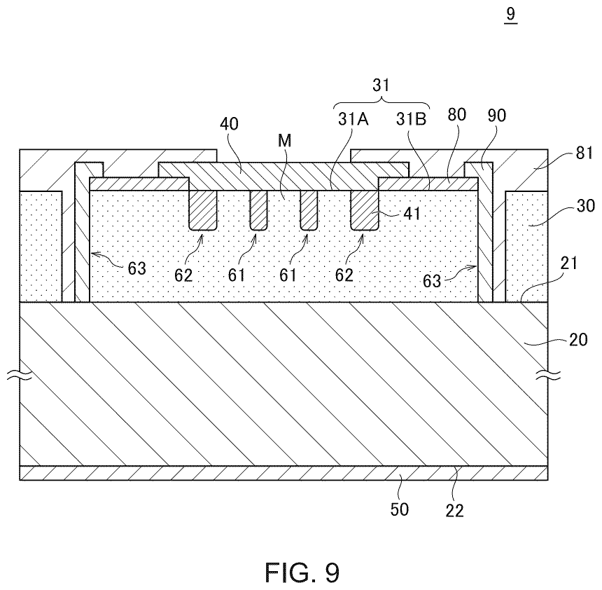

FIG. 9 is a schematic cross-sectional view illustrating the configuration of a junction barrier Schottky diode 9 according to a ninth embodiment of the technology described herein.

As illustrated in FIG. 9, the junction barrier Schottky diode 9 according to the ninth embodiment differs from the junction barrier Schottky diode 8 according to the eighth embodiment in that the protective film 81 is partially filled in the trench 63. Other basic configurations are the same as those of the junction barrier Schottky diode 8 according to the eighth embodiment, so the same reference numerals are given to the same elements, and overlapping description will be omitted. Thus, the trench 63 may be partially filled with a member (such as the protective film 81) other than the conductive member 90.

### Tenth Embodiment

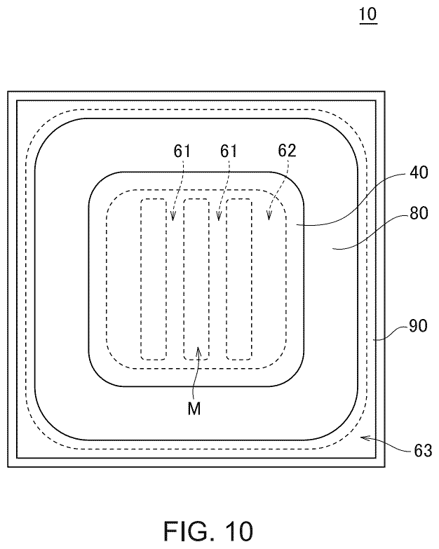

FIG. 10 is a schematic plan view illustrating the configuration of a junction barrier Schottky diode 10 according to a tenth embodiment of the technology described herein.

As illustrated in FIG. 10, the junction barrier Schottky diode 10 according to the tenth embodiment differs from the junction barrier Schottky diode 1 according to the first embodiment in that, in a plan view as viewed in the stacking direction, the outer peripheral wall of the trench 63 is rectangle, and the inner peripheral wall thereof has rounded corners. Other basic configurations are the same as those of the junction barrier Schottky diode 1 according to the first embodiment, so the same reference numerals are given to the same elements, and overlapping description will be omitted. Thus, the outer and inner peripheral walls of the trench 63 may have different shapes in a plan view as viewed in the stacking direction.

### Eleventh Embodiment

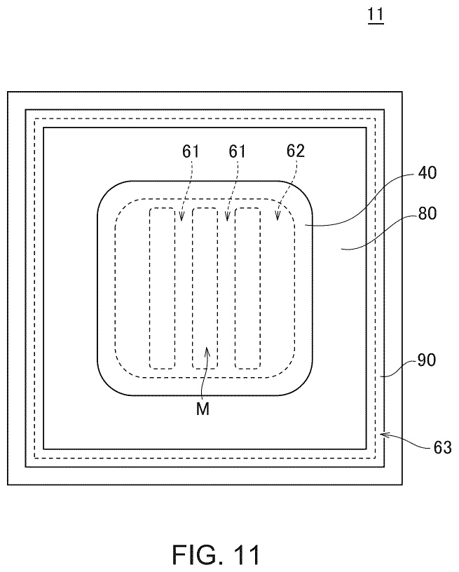

FIG. 11 is a schematic plan view illustrating the configuration of a junction barrier Schottky diode 11 according to an eleventh embodiment of the technology described herein.

As illustrated in FIG. 11, the junction barrier Schottky diode 11 according to the eleventh embodiment differs from the junction barrier Schottky diode 1 according to the first embodiment in that, in a plan view as viewed in the stacking direction, the outer and inner peripheral walls of the trench 63 are both rectangle, and the corners thereof are not rounded. Other basic configurations are the same as those of the junction barrier Schottky diode 1 according to the first embodiment, so the same reference numerals are given to the same elements, and overlapping description will be omitted. Thus, the corners of the trench 63 need not necessarily be rounded as viewed in the stacking direction.

### Twelfth Embodiment

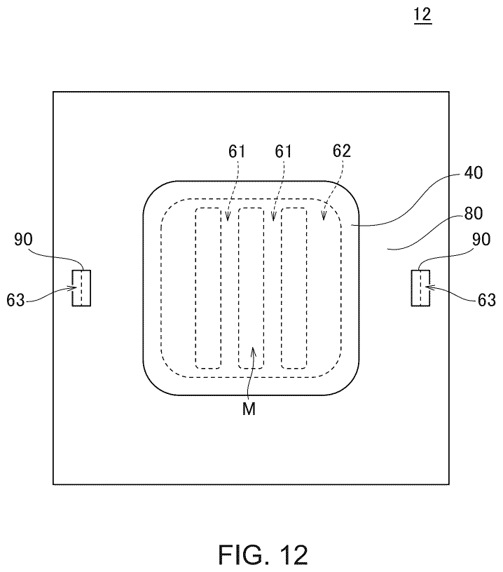

FIG. 12 is a schematic plan view illustrating the configuration of a junction barrier Schottky diode 12 according to a twelfth embodiment of the technology described herein.

As illustrated in FIG. 12, the junction barrier Schottky diode 12 according to the twelfth embodiment differs from the junction barrier Schottky diode 1 according to the first embodiment in that, in a plan view as viewed in the stacking direction, the trench 63 dies not have a ring shape but is partially provided at two locations. Other basic configurations are the same as those of the junction barrier Schottky diode 1 according to the first embodiment, so the same reference numerals are given to the same elements, and overlapping description will be omitted. Thus, the trench 63 need not have a ring shape in a plan view and may be provided at a desired position within the outer peripheral area 31B.

### Thirteenth Embodiment

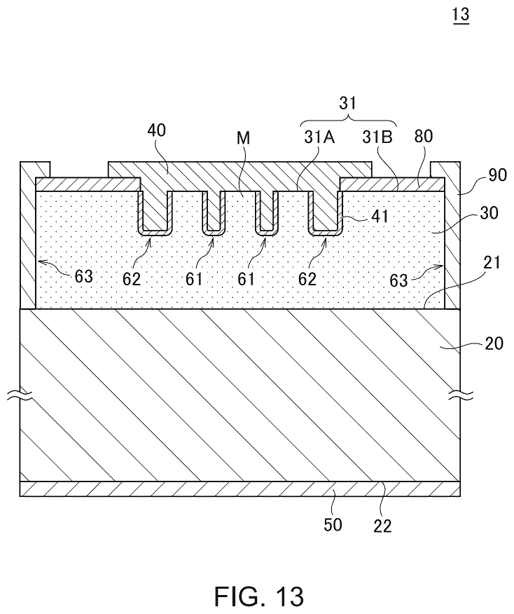

a schematic cross-sectional view FIG. 13 is illustrating the configuration of a junction barrier Schottky diode 13 according to a thirteenth embodiment of the technology described herein.

As illustrated in FIG. 13, the junction barrier Schottky diode 13 according to the thirteenth embodiment differs from the junction barrier Schottky diode 1 according to the first embodiment in that the p-type semiconductor layer 41 only covers the inner wall of each of the center and outer peripheral trenches 61 and 62, and the remaining area inside each of the center and outer peripheral trenches 61 and 62 is filled with the same metal material as that of the anode electrode 40. Other basic configurations are the same as those of the junction barrier Schottky diode 1 according to the first embodiment, so the same reference numerals are given to the same elements, and overlapping description will be omitted. Thus, the p-type semiconductor layer 41 may be provided so as to only cover the inner wall of each of the center and outer peripheral trenches 61 and 62.

### Fourteenth Embodiment

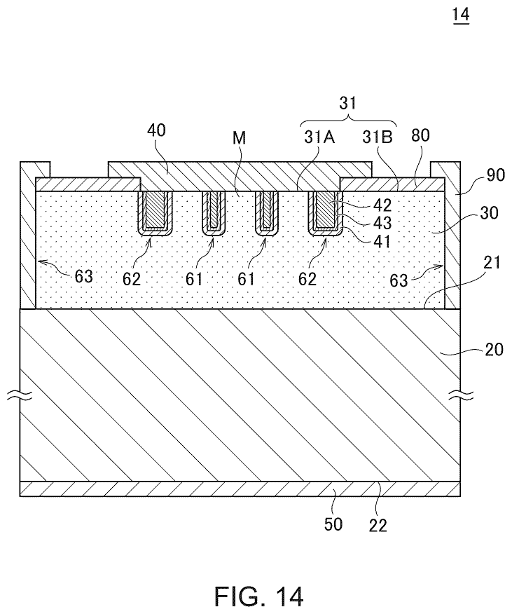

FIG. 14 is a schematic cross-sectional view illustrating the configuration of a junction barrier Schottky diode 14 according to a fourteenth embodiment of the technology described herein.

As illustrated in FIG. 14, the junction barrier Schottky diode 14 according to the fourteenth embodiment differs from the junction barrier Schottky diode 13 according to the thirteenth embodiment in that the center and outer peripheral trenches 61 and 62 are filled with an n-type semiconductor layer 42 and that a metal layer 43 is provided between the p-type semiconductor layer 41 and the n-type semiconductor layer 42. Other basic configurations are the same as those of the junction barrier Schottky diode 13 according to the thirteenth embodiment, so the same reference numerals are given to the same elements, and overlapping description will be omitted.

The n-type semiconductor layer 42 is brought into Schottky-contact with the anode electrode 40 and acts to reduce a contact resistance generated when the anode electrode 40 and p-type semiconductor layer 41 directly contact each other. The material of the n-type semiconductor layer 42 may be a semiconductor material having a small band gap and capable of exhibiting both p- and n-conduction types, for example, a material in which an n-type dopant is introduced into a material similar to that of the p-type semiconductor layer 41. As one example, an n-type Ge or n-type Si can be selected as the n-type semiconductor layer 42.

The metal layer 43 is provided between the p-type semiconductor layer 41 and the n-type semiconductor layer 42 and acts to prevent formation of a depletion layer due to direct contact between the p-type semiconductor layer 41 and the n-type semiconductor layer 42. The material of the metal layer 43 may be Al, Pt, Pd, or the like. As one example, when an n-type Si and a p-type Si are selected as the n-type and p-type semiconductor layers 42 and 41, respectively, Al having a thickness of about 100 nm can be selected as the metal layer 43.

As described above, in the junction barrier Schottky diode 14 according to the present embodiment, the n-type semiconductor layer 42 and metal layer 43 are interposed between the anode electrode 40 and the p-type semiconductor layer 41, so that a resistance value between the anode electrode 40 and the p-type semiconductor layer 41 is reduced, thus making it possible to achieve a higher surge resistance.

While some embodiments of the present disclosure has been described, the present disclosure is not limited to the above embodiment, and various modifications may be made within the scope of the present disclosure, and all such modifications are included in the present disclosure.

For example, although gallium oxide is used as the material of the semiconductor substrate 20 and drift layer 30 in the above embodiments, the material of the semiconductor substrate 20 and drift layer 30 is not limited to gallium oxide, but materials such as silicon oxide (Sic), gallium nitride (GaN), aluminum nitride (AlN), diamond (C), silicon (Si), germanium (Ge), silicon germanium (SiGe), or gallium arsenide (GaAs) may be used. Even when these materials are used for the semiconductor substrate 20 and drift layer 30, the same effects as those described above can be achieved based on the same principle as that when gallium oxide is used.

Further, although the drift layer 30 has the center and outer peripheral trenches 61 and 62, one of them may be omitted.

The technology according to the present disclosure includes the following configuration examples but not limited thereto.

A junction barrier Schottky diode according to one aspect of the present disclosure includes: a semiconductor substrate; a drift layer provided on the semiconductor substrate; a field insulating film covering an annular outer peripheral area of an upper surface of the drift layer; an anode electrode brought into Schottky-contact with a center area of the upper surface of the drift layer that is surrounded by the outer peripheral area, an end portion of the anode electrode being positioned on the field insulating film; a cathode electrode brough into ohmic contact with the semiconductor substrate; a p-type semiconductor layer embedded in a first trench formed in the center area of the drift layer so as to be connected to the anode electrode and the drift layer; and a conductive member contacting the field insulating film and electrically connected to the semiconductor substrate. With this configuration, an electric charge accumulated in the drift layer is relaxed upon application of a backward voltage, making it possible to prevent a dielectric breakdown due to accumulation of an electric charge.

In the above junction barrier Schottky diode, the conductive member may be partially positioned on the field insulating film. This allows an electric charge to be extracted more efficiently.

In the above junction barrier Schottky diode, the drift layer may further have a second trench formed so as to reach the semiconductor substrate, and the conductive member may be embedded in the second trench. This allows the conductive member to be retained in the second trench.

In the above junction barrier Schottky diode, the second trench may be formed in a ring shape so as to surround the anode electrode in a plan view as viewed in the stacking direction. This allows an electric charge to be extracted more efficiently.

In the above junction barrier Schottky diode, the conductive member may include a part positioned at the bottom of the second trench and a part positioned at the upper portion of the second trench, which are made of different metal materials. This facilitates formation of the conductive member.

In the above junction barrier Schottky diode, at least a part of the conductive member may be made of the same metal material as that of the anode electrode. This facilitates formation of the conductive member.

### EXAMPLES

### Example 1

Two simulation models having the same structures as those of the junction barrier Schottky diodes 13 and 15 illustrated in FIGS. 13 and 15 were assumed, and a space charge accumulated in a part of the drift layer 30 just below the field insulating film 80 was simulated with a backward voltage of 1200 V applied between the anode electrode 40 and cathode electrode 50. The dopant concentration of the semiconductor substrate 20 was set to 1×10¹⁸ cm⁻³, and the dopant concentration of the drift layer 30 was to 3×10¹⁶ cm⁻³. The thickness of the drift layer 30 was set to 10 μm. The depths of the center and outer peripheral trenches 61 and 62 were both set to 2 μm. The width of the center and outer peripheral trenches 61 and 62 in the cross section illustrated in FIG. 1B and the width of the upper surface 31 of the drift layer 30 (i.e., width of the mesa region M) were both set to 1.0 μm. The anode electrode 40 was made of Ni, and the cathode electrode 50 was formed of a laminated film of Ti and Au. The p-type semiconductor layer 41 was made of NiO having a thickness of 200 nm. As the field insulating film 80, an SiO₂ film having a thickness of 300 nm was used. The trench 63 was formed at a position separated by 14 μm from the outer peripheral wall of the outer peripheral trench 62 so as to have a width of 50 μm and a depth of 10 μm. The material of the conductive member 90 filled in the trench 63 was the same as that of the anode electrode 40. The distance T between the conductive member 90 and anode electrode 40 was set to 8 μm.

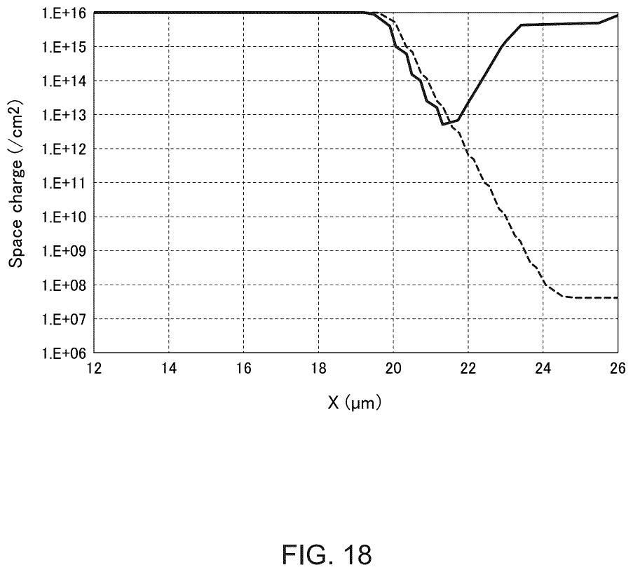

The simulation results are illustrated in the graph of FIG. 18. In the graph of FIG. 18, the horizontal axis represents a distance X from the outer peripheral wall of the outer peripheral trench 62 (see FIG. 1). The solid line denotes the characteristics of the junction barrier Schottky diode 13, and the dashed line denotes the characteristics of the junction barrier Schottky diode 15.

As illustrated in the graph of FIG. 18, in the junction barrier Schottky diode 13 provided with the conductive member 90, the space charge was 1×10¹⁶ cm⁻² in the area within about 8 μm from the outer peripheral wall of the outer peripheral trench 62, and an area in which the space charge reduced outward therefrom appeared; however, the space charge increased toward the conductive member 90 to 4.5×10¹⁵ cm⁻² in the vicinity of the conductive member 90. This reveals that an electric charge has been extracted by the conductive member 90.

On the other hand, in the junction barrier Schottky diode 15 not provided with the conductive member 90, the space charge was 1×10¹⁶ cm⁻² in the area within about 8 μm from the outer peripheral wall of the outer peripheral trench 62, but it significantly reduced outward therefrom to 1×10⁸ cm⁻² or less in an area separated by about 12 μm or more from the outer peripheral wall of the outer peripheral trench 62. This reveals that, in the junction barrier Schottky diode 15 not provided with the conductive member 90, there is no space for discharging an electric charge, and thus accumulation of the electric charge occurs.

The electric field strength applied to the field insulating film 80 was 11.9 MV/cm in the junction barrier Schottky diode 13 and 12.1 MV/cm in the junction barrier Schottky diode 15.

### Example 2

A simulation model having the same structure as that of the junction barrier Schottky diode 13 illustrated in FIG. 13 was assumed, and a space charge accumulated in a part of the drift layer 30 just below the field insulating film 80 was simulated with the distance T between the conductive member 90 and anode electrode 40 set to 8 μm, 50 μm, 100 μm, 150 μm, or 200 μm. Other conditions were the same as those in Example 1.

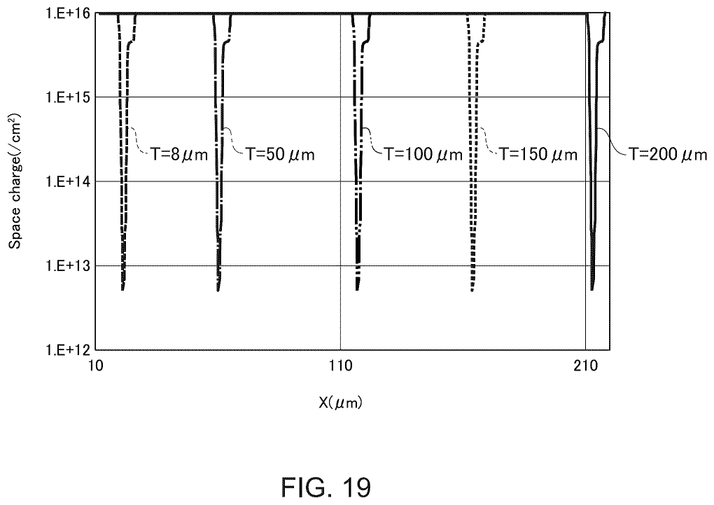

The simulation results are illustrated in the graph of FIG. 19. The graph of FIG. 19 reveals that the distribution of an electric charge does not change depending on the distance T and that the space charge is maintained high excluding in the vicinity of the edge of the conductive member 90.

What is claimed is:

1. A junction barrier Schottky diode comprising:
a semiconductor substrate;
a drift layer provided on the semiconductor substrate;
a field insulating film covering an annular outer peripheral area of an upper surface of the drift layer;
an anode electrode brought into Schottky-contact with a center area of the upper surface of the drift layer that is surrounded by the outer peripheral area, an end portion of the anode electrode being positioned on the field insulating film;
a cathode electrode brough into ohmic contact with the semiconductor substrate;
a p-type semiconductor layer embedded in a first trench formed in the center area of the drift layer so as to be connected to the anode electrode and the drift layer; and
a conductive member contacting the field insulating film and electrically connected to the semiconductor substrate.

2. The junction barrier Schottky diode as claimed in claim 1, wherein the conductive member is partially positioned on the field insulating film.

3. The junction barrier Schottky diode as claimed in claim 1,
wherein the drift layer further has a second trench formed so as to reach the semiconductor substrate, and
wherein the conductive member is embedded in the second trench.

4. The junction barrier Schottky diode as claimed in claim 3, wherein the second trench is formed in a ring shape so as to surround the anode electrode in a plan view as viewed in a stacking direction.

5. The junction barrier Schottky diode as claimed in claim 3, wherein the conductive member includes a part positioned at a bottom of the second trench and a part positioned at an upper portion of the second trench, which are made of different metal materials.

6. The junction barrier Schottky diode as claimed in claim 1, wherein at least a part of the conductive member is made of a same metal material as that of the anode electrode.
